(19) United States
(12) Patent Application Publication
(10) Pub. No.: US 2019/0081145 A1
(43) Pub. Date: Mar. 14, 2019

(54) CONTACT TO SOURCE/DRAIN REGIONS AND METHOD OF FORMING SAME

(71) Applicant: GLOBALFOUNDRIES Inc., Grand Cayman (KY)

(72) Inventors: Ruilong Xie, Schenectady, NY (US); Christopher M. Prindle, Poughkeepsie, NY (US); Nigel G. Cave, Saratoga Springs, NY (US); Mark V. Raymond, Latham, NY (US)

(21) Appl. No.: 15/701,678

(22) Filed: Sep. 12, 2017

(51) Int. Cl. H01L 29/417; H01L 21/8238; H01L 27/092; H01L 29/08; H01L 29/78; H01L 29/66

(52) U.S. Cl. CPC H01L 29/41783; H01L 21/823814; H01L 27/0924; H01L 29/66545; H01L 29/0847; H01L 29/7833; H01L 21/823828; H01L 21/823821

(57) ABSTRACT

A structure and method for forming sets of contact structures to source/drain regions of complimentary N-type field effect transistors (NFETs) and P-type field effect transistors (PFETs). The structure including a NFET structure including a first fin positioned on a substrate and a PFET structure including a second fin positioned on the substrate, wherein a source/drain region (S/D) of the first fin and a S/D of the second fin include non-uniform openings at an uppermost surface. A method of forming non-uniformly openings in the S/Ds of the complimentary NFETs and PFETs including forming mask on the PFET to protect the structure during formation of openings in the NFET S/D. A method of forming non-uniform openings in the S/D of the complimentary NFETs and PFETs including reducing the epitaxially growth of the NFET S/D to form an opening therein.

### BACKGROUND

The present disclosure relates to integrated circuit technology, and more specifically, to source/drain regions in complimentary N-type field effect transistors (NFETs) and P-type field effect transistors (PFETs) and methods of forming contact structures thereto.

Conventional integrated circuit (IC) (i.e., chip) formation generally occurs on the surface of a semiconductor substrate, e.g., silicon wafer. ICs may include a variety of interconnected semiconductor devices such as resistors, transistors, capacitors, etc., formed on the surface of the semiconductor substrate. Due to the large number of devices and complex layout of the ICs, the devices cannot be connected within the same device level. The devices may therefore be interconnected, for example, by a complex wiring system formed in one or more layers above the device level. The wiring system may include, for example, stacked metal containing layers, i.e., metallization layers, which include metal wires providing intra-level electrical connections. The wiring system may also include layers stacked between the metallization layers including vertical structures, i.e., vias for inter-level electrical connections between the metallization.

The wiring system may be electrically connected to the semiconductor devices of the device level by a local interconnect region. For example, the local interconnect region may include conductive contact structures (CAs) to provide an electrical connection between a metal layer of the wiring system and a semiconductor device of the device level. The contact structure may extend through the dielectric layer of the device level which encloses the semiconductor devices. The contact may structurally connect the active portion of a semiconductor device in the device layer (e.g., source/drain or gate region of a transistor) to a metal wire in a metal layer of the wiring system.

Ever-increasing device density has created a demand for smaller-scale devices. One measurement of scale in a device layer is the length of a gate structure plus the amount of space between the gate structure and another gate structure, i.e., contact poly pitch (CPP). Reduced CPP may require that contact structures connected to structures between gates also be scaled down in order to fit therebetween. Reducing the size of the contact structures may result in a smaller interface area between the contact structures and the structure to which it connects. This interface area reduction between the contact structure and the device-level structure may increase the electrical resistance at the interface, thereby impeding performance of the contact structure. As a result, it may be desirable to increase the interface area between the contact structure and device-level structure by other means. For example, with respect to a contact structure interfacing with a source/drain region of a transistor, a gouge may be formed within the source/drain region before forming the contact structure thereto. The contact structure may then be formed within the gouge of the source and drain region which provides a larger interface area between the contact structure and the source/drain region.

Some products require P-type field effect transistors (PFETs) to be formed together with N-type field effect transistors (NFETs) in a single device layer. For example, a set of complimentary NFET and PFETs may be used to form a switching circuit for an IC structure. Conventionally, forming contact structures to the source/drain regions of complimentary NFETs and PFETs includes uniform gouging of the source/drain regions. Uniform gouging of the PFET and NFET source/drain regions, however, does not accommodate the structural differences between PFETs and NFETs. PFETs and NFETs may require different amounts of gouging to form their source/drain regions, which poses a technical obstacle to efficient processing.

For, example, formation of a PFET may include forming P-type source/drain regions in the fin of the PFET by forming positively charged particles, i.e., “holes”, therein. In fin field effect transistor (FinFET) technology (e.g., 14 nanometer technology and beyond), the formation of a source/drain region for a PFET may also include the use of an epi stressor which generates a compressive strain in the channel of the PFET to enhance the mobility of holes through the channel. Therefore, when forming a contact structure to the source/drain regions of a PFET, it may be desirable to only slightly gouge into the source/drain region in order to prevent damage to the epi stressor and preserve the compressive stress in the channel of the PFET. Slightly gouging the source/drain region of the PFET may increase the interface area between the contact structure and the source/drain region, thus reducing the resistance at the interface.

In contrast, the formation of a source/drain region for an NFET may include forming N-type source/drain regions in the fin of the NFET by forming negatively charged particles, i.e., electrons, therein. The formation of N-type source/drain regions may not include the use of an epi stressor. When forming a contact structure to the source/drain region of an NFET, it may be desirable to gouge the contact structure deeply within the source/drain region. For example, deeper gouging may allow for an increased interface area between the contact structure and the source/drain region of the NFET, thus reducing the conduct resistance.

### SUMMARY

A first aspect of the disclosure is directed to an integrated circuit (IC) structure including: an N-type field effect transistor (NFET) structure including a first fin positioned on a substrate; a P-type field effect transistor (PFET) structure including a second fin positioned on the substrate, the first fin laterally separated from the second fin; a gate structure positioned on the first fin and the second fin; a first source/drain region of the first fin positioned adjacent to the gate structure, the first source/drain region including a first opening in an upper portion of the first source/drain region; and a second source/drain region of the second fin positioned adjacent to the gate structure, wherein an uppermost surface of the second source/drain region is positioned higher than a bottommost surface of the first opening in the first source/drain region.

A second aspect of the disclosure is related to a method of forming an integrated circuit (IC) structure, the method including: forming a sacrificial gate structure on a N-type fin and a P-type, each fin positioned on a substrate, the N-type fin laterally separated from the P-type fin; forming a first source/drain region on the P-type fin, the first source/drain region adjacent to each side of the sacrificial gate structure; forming a liner above the first source/drain region; forming a pair of openings in the N-type fin, the set of openings adjacent to each side of the sacrificial gate structure; and forming a second source/drain region in the set of openings in the N-type fin, wherein a vertical cross-section of an uppermost surface of the second source/drain region is substantially U-shaped.

A third aspect of the disclosure is related to a method of forming an integrated circuit (IC) structure, the method including: forming a first source/drain region on a first fin of a P-type field effect transistor (PFET) positioned on a substrate, the first source/drain region positioned laterally adjacent to a gate structure positioned on the first fin; forming a second source/drain region on a second fin of an N-type field effect transistor (NFET) positioned on the substrate, the second source/drain region positioned laterally adjacent to the gate structure positioned on the second fin, and wherein the first fin is laterally separated from the first fin; forming a liner along sidewalls of the gate structure; removing a first portion of the first source/drain region and a second portion of the second source/drain region; forming a protective mask above the first source/drain region of the PFET; and removing a third portion of the second source/drain region.

### BRIEF DESCRIPTION OF THE DRAWINGS

The embodiments of this disclosure will be described in detail, with reference to the following figures, wherein like designations denote like elements, and wherein:

FIG. 1 shows a plan view of an initial structure for forming a set of contact structures to source/drain regions of a complimentary NFET and PFET, according to embodiments of the disclosure.

FIGS. 2a and 2b show cross-sectional views of the initial structure of FIG. 1 at lines a-a and b-b according to embodiments of the disclosure.

FIGS. 3a and 3b show cross-sectional views of forming source/drain regions in a fin of the PFET of FIG. 1, according to embodiments of the disclosure.

FIGS. 4a and 4b show cross-sectional views of forming source/drain regions in a fin of the NFET of FIG. 1 including openings therein, according to embodiments of the disclosure.

FIGS. 5a and 5b show cross-sectional views of forming dummy contact structures and removing dummy gate body structures source/drain regions, according to embodiments of the disclosure.

FIGS. 6a and 6b show cross-sectional views of forming a set of replacement metal gate, according to embodiments of the disclosure.

FIG. 7 shows a plan view of forming non-contact regions at the edges of the dummy contact structures, according to embodiments of the disclosure.

FIGS. 8a and 8b show forming replacement contact structure, according to embodiments of the disclosure.

FIGS. 9a and 9b show cross-sectional views of forming additional openings in the source/drain regions of fins, according to embodiments of the disclosure.

FIGS. 10a and 10b show cross-sectional views of forming source/drain regions in the fins of complementary transistors, according to embodiments of the disclosure.

FIGS. 11a and 11b show cross-sectional views of forming openings in the source/drain regions of FIGS. 10a and 10b, according to embodiments of the disclosure.

FIGS. 12a and 12b show cross-sectional views of forming a mask on the PFET and forming deeper openings in the source/drain regions of the NFET of FIG. 11a, according to embodiments of the disclosure.

FIGS. 13a and 13b show cross-sectional views of removing the mask in FIG. 10b, and forming a set of contact structures to the source/drain regions of complementary transistors according to embodiments of the disclosure.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific embodiments in which the present teachings may be practiced. These embodiments are described in sufficient detail to enable those skilled in the art to practice the present teachings and it is to be understood that other embodiments may be used and that changes may be made without departing from the scope of the present teachings. The following description is, therefore, merely illustrative.

Embodiments of the present disclosure provide a structure and method for forming contact structures to source/drain regions of complimentary P-type field effect transistors (PFETs) and N-type field effect transistors (NFETs) in a semiconductor structure. Embodiments of the disclosure provide for different amounts of source/drain gouging in the PFET and NFET transistors of one device layer. Methods according to the disclosure may include forming the source/drain regions for the PFET separately from the source/drain regions for the NFET, allowing for different gouging methods to be used on each. Methods according to the disclosure may alternatively include forming a mask over the source/drain regions for the PFET during gouging of the source/drain regions for the NFET.

Embodiments of the present disclosure may increase the area of the physical interface between a contact structure and the source/drain region to which it is formed. Embodiments of the present disclosure may also allow for contact structures to be formed to source/drain regions of complimentary NFET and PFET structures based on the different desirable extents of gouging for each, as set forth above.

As used herein, the term “gouging” may include forming an opening within a portion of a source/drain region of a semiconductor fin. For example, “gouging” could mean etching an opening in a source/drain region of a semiconductor fin. In another non-limiting example, “gouging” could include forming a source/drain region of a semiconductor fin in a manner such that an opening is formed in the source/drain region as part of its formation. The term “uniform gouging” may indicate openings formed within respective source/drain regions, the value of whose respective dimensions are within +/- 10% of one other. The term “non-uniform gouging” may indicate openings formed within respective source/drain regions and do not meet the requirements for “uniform gouging.”

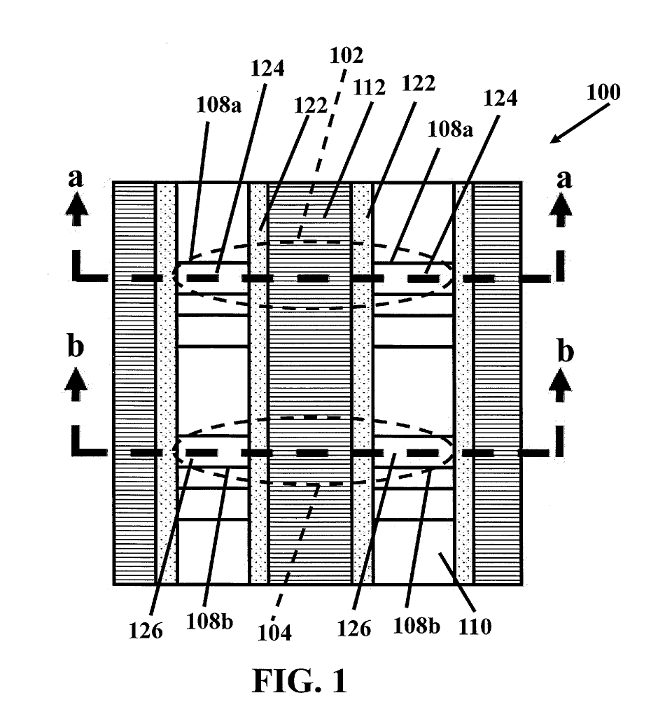

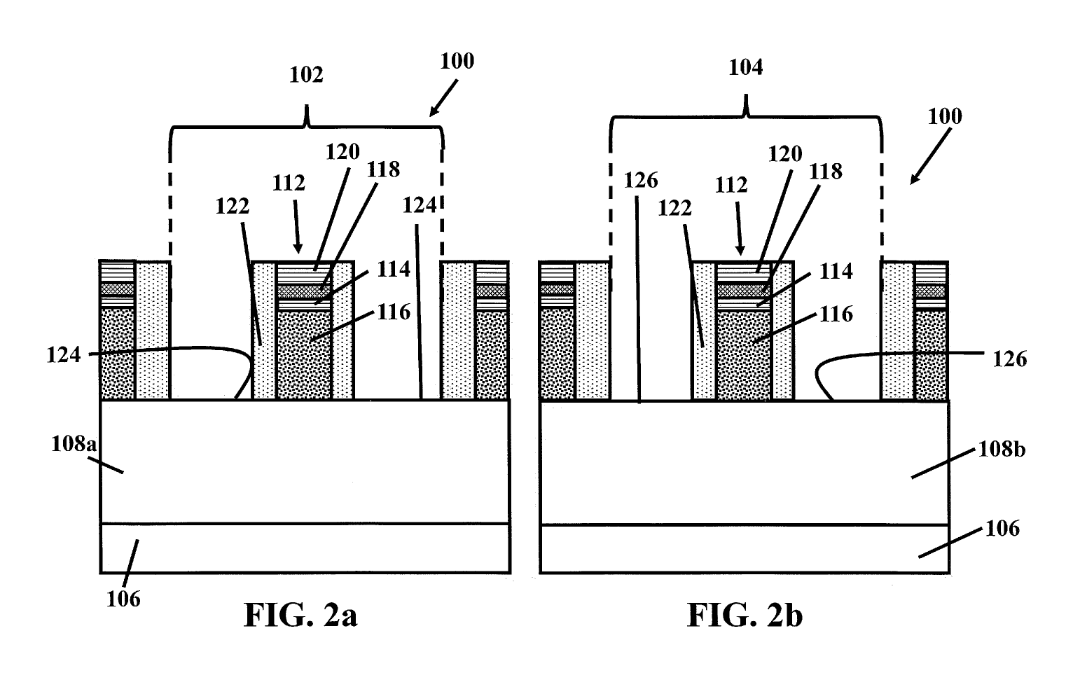

Turning to the figures, FIG. 1 and FIG. 2a show an initial structure 100 for forming gouged source/drain regions of an NFET, according to embodiments of the disclosure. FIG. 1 shows a plan view of initial structure 100 and FIG. 2a shows a cross-sectional view of NFET region 102 (in phantom in FIG. 1) of initial structure 100 at line a-a of FIG. 1.

As shown in FIGS. 1 and 2a, initial structure 100 may include a substrate 106 upon which the remainder of the initial structure may be formed. Substrate 106 may be formed using any now known or later developed semiconductor fabrication techniques for forming a substrate. Substrate 106 may include but is not limited to silicon, germanium, silicon germanium, silicon carbide, and those consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{A1}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entirety of each layer may be strained. Although not shown, substrate 106 may alternatively include a silicon-on-insulator (SOI) substrate formed by conventional semiconductor techniques for forming an SOI substrate.

As shown in FIGS. 1 and 2a, a fin 108a for an NFET structure may be formed vertically extending from substrate 106 in NFET region 102. Fin 108a may be formed on substrate 106 by conventional semiconductor fabrication techniques for forming vertical fins for a field effect transistor (FET). For example, fin 108a may be formed by patterned epitaxial growth of substrate 106 and/or patterned etching of substrate 106, using a mask (not shown). “Epitaxy” or “epitaxial growth,” as used herein, refers to a process by which a thin layer of single-crystal or large-grain polycrystalline material is deposited on a base material with similar crystalline properties. Etching generally refers to the removal of material from a substrate (or structures formed on the substrate), and is often performed with a mask in place so that material may selectively be removed from certain areas of the substrate, while leaving the material unaffected, in other areas of the substrate. There are generally two categories of etching, (i) wet etch and (ii) dry etch. Wet etch is performed with a solvent (such as an acid) which may be chosen for its ability to selectively dissolve a given material (such as oxide), while, leaving another material (such as polysilicon) relatively intact. This ability to selectively etch given materials is fundamental to many semiconductor fabrication processes. A wet etch will generally etch a homogeneous material (e.g., oxide) isotropically, but a wet etch may also etch single-crystal materials (e.g., silicon wafers) anisotropically. Dry etch may be performed using a plasma. Plasma systems can operate in several modes by adjusting the parameters of the plasma. Ordinary plasma etching produces energetic free radicals, neutrally charged, that react at the surface of the wafer. Since neutral particles attack the wafer from all angles, this process is isotropic. Ion milling, or sputter etching, bombards the wafer with energetic ions of noble gases which approach the wafer approximately from one direction, and therefore this process is highly anisotropic. Reactive-ion etching (RIE) operates under conditions intermediate between sputter and plasma etching and may be used to produce deep, narrow features, such as STI trenches.

Once fin 108a has been formed on substrate 106, an insulating layer 110 (see FIG. 1) may be formed on substrate 106 and adjacent to the fin to electrically isolate it from nearby structures such as other fins, not shown. Although not shown, insulating layer 110 may be formed to cover only a bottom portion of fin 108a extending from substrate 106. An upper portion of fin 108a may remain exposed, for example, for the formation of source/drain regions therein. Insulating layer 110 may be formed on substrate 106 by conventional semiconductor fabrication techniques for forming an oxide layer on a substrate. For example, insulating layer 110 may be formed on substrate 106 by deposition, planarization, patterning and etching. Insulating layer 110 may include, for example, silicon oxide (SiO₂) and/or any other now known or later developed oxide layer materials.

Initial structure 100 may also include a dummy gate semiconductor structure 112 formed over fin 108a to prevent the covered portion of fin 108a from being processed during formation of source/drain regions in the fin. As shown in the plan view of FIG. 1, dummy gate semiconductor structure 112 may traverse fin 108a. Dummy gate semiconductor structure 112 may include, for example, a dummy gate body 116, a first gate hard mask 114, a dummy gate cap 118, and a second gate hard mask 120, formed on fins 108a and 108b. For example, dummy gate body 116 may be formed on upper surfaces 124, 126 of fins 108a, 108b, respectively. First gate hard mask 114 may then be formed on dummy gate body 116. Dummy gate cap 118 and second gate hard mask 120 may be formed on first gate hard mask 114. Dummy gate cap 118 and second gate hard mask 120 may, for example, prevent the remainder of the dummy gate body structure from being processed and/or removed during further processing of fin 108a.

Dummy gate semiconductor structure 112 may be formed by conventional semiconductor fabrication techniques for forming a dummy contact structure. For example, first gate hard mask 114, dummy gate body 116, dummy gate cap 118, and second gate hard mask 120 may be formed on fins 108a, 108b by deposition, patterning and etching using a mask (not shown). As used herein, the term “depositing” may include any now known or later developed technique appropriate for deposition, including but not limited to, for example: chemical vapor deposition (CVD), low-pressure CVD (LPCVD), plasma-enhanced CVD (PECVD), semi-atmosphere CVD (SACVD) high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, and evaporation.

First gate hard mask 114, dummy gate body 116, dummy gate cap 118, and second gate hard mask 120 may include conventional materials for a dummy gate body structure. For example, first gate hard mask 114 and second gate hard mask 120 may include silicon oxide (SiO₂), and/or any other now known or later developed gate hard mask materials. Dummy gate body 116 may include amorphous silicon (a-Si) on a silicon oxide (SiO₂) layer, and/or any other now known or later developed dummy gate body materials. Dummy gate cap 118 may include silicon nitride (SiN), and/or any other now known or later developed cap materials for a dummy gate body structure.

Once dummy gate semiconductor structure 112 is formed on fin 108a, spacers 122 may be formed on either side of the dummy gate body structure to electrically insulate a replacement metal gate structure which may subsequently replace dummy gate semiconductor structure 112. As shown in the plan view of FIG. 1, spacers 122 may traverse fin 108a. Spacers 122 may also be formed by conventional semiconductor fabrication techniques. For example, spacers 122 may be formed on the sidewalls of dummy gate semiconductor structure 112 by a conformal dielectric deposition, followed by anisotropic etch. Spacers 122 may include, for example, SiBCN, SiCO, and/or any other now known or later developed materials for spacers for a gate structure.

As shown in FIGS. 1 and 2a, after dummy gate semiconductor structure 112 and spacers 122 have been formed on fin 108a, surfaces 124 of fin 108a may remain exposed to be further processed for form source and drain regions within the fin.

Turning to FIGS. 1 and 2b together, FIG. 2b shows a cross-sectional view of initial structure 100 at line b-b within PFET region 104 (in phantom in FIG. 1) of FIG. 1. PFET region 104 may include substantially the same structure as NFET region 102 aside from being used to form a PFET structure in subsequent processing. For example, PFET region 104 may include a fin 108b vertically extending from substrate 106. As shown in FIG. 1, fin 108b may be laterally separated from fin 108a on substrate 106. Fin 108b may, for example, be formed by the same processes as fin 108a. As also shown in FIG. 1, insulating layer 110 may also be positioned on the substrate on either side of fin 108b. Dummy gate semiconductor structure 112 and spacers 122 may be formed to extend into PFET region 104 and traverse fin 108b. Similarly to fin 108a, after dummy gate semiconductor structure 112 and spacers 122 have been formed on fin 108a, surfaces 126 of fin 108a may remain exposed to be further processed to form source and drain regions within the fin. It should be understood that structures in PFET region 104 may be formed by the same methods and include the same types of materials as structures with the same reference numbers as structures in NFET region 102 set forth above.

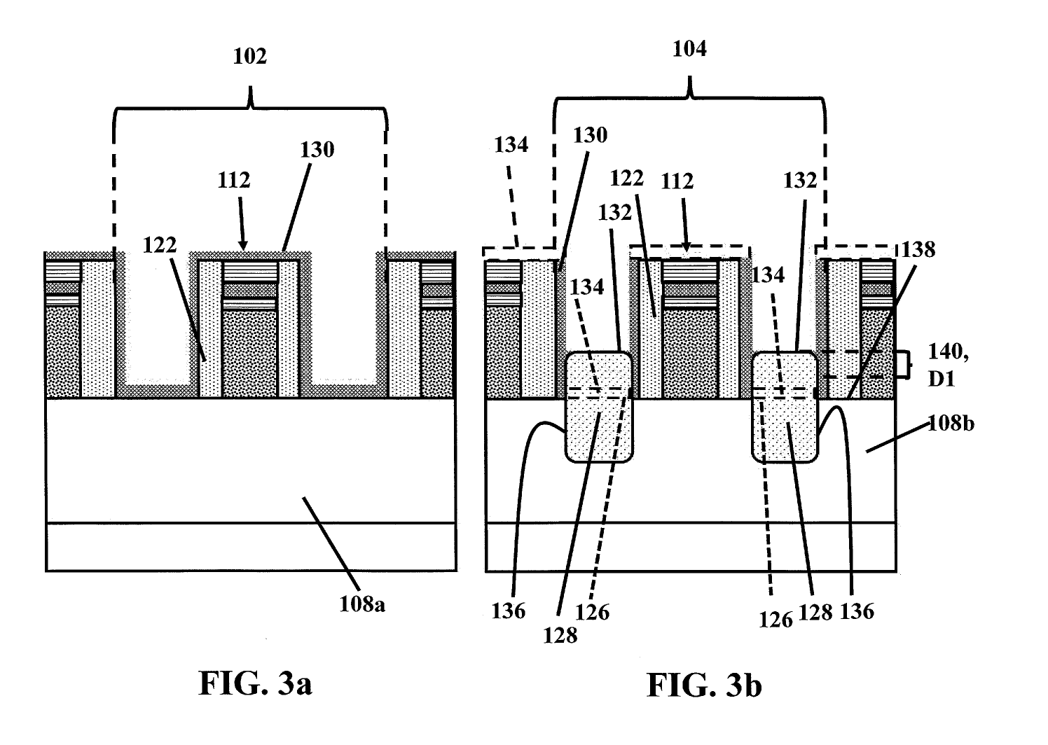

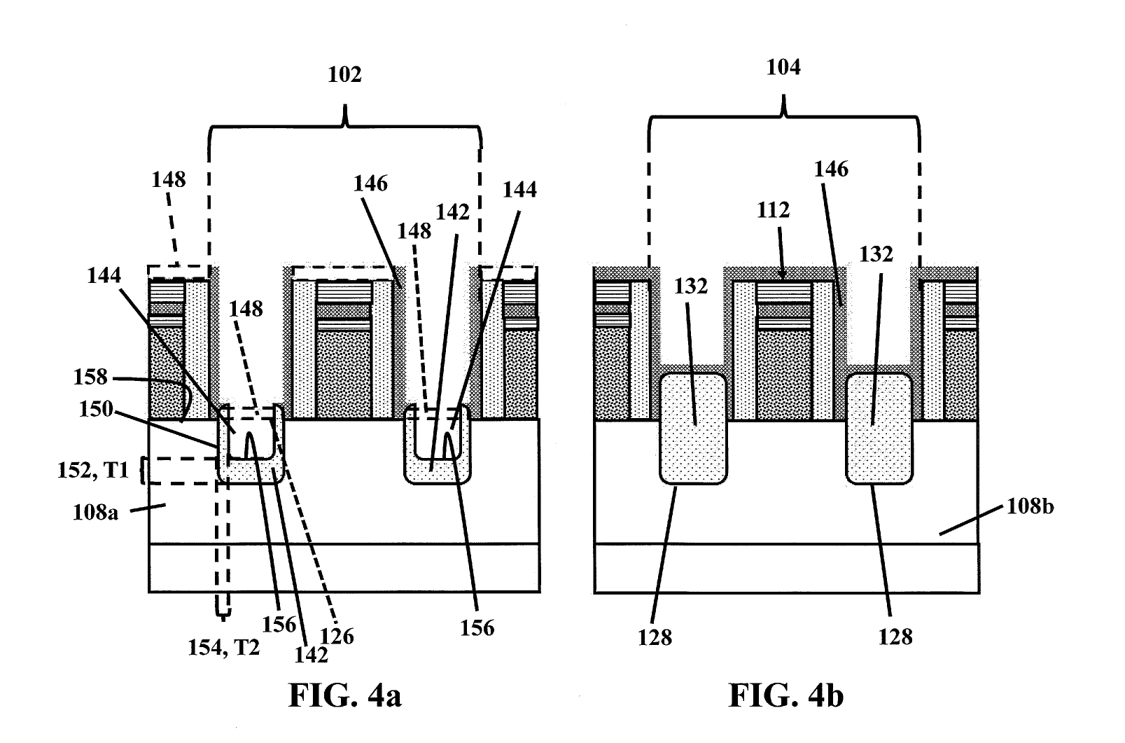

FIG. 3b shows first forming source/drain regions 128 of fin 108b exclusively in PFET region 104, according to embodiments of the disclosure. Forming source/drain regions 128 in fin 108b separately from source/drain regions 142 (see FIG. 4a) may allow, for example, different processing of the source drain regions including non-uniform gouging. As shown in FIG. 3a, NFET region 102 may remain substantially intact during the formation of source/drain regions 128 in PFET region 104.

As shown in FIGS. 3a and 3b, before forming source/drain regions 128, a first liner 130 may be formed over dummy gate semiconductor structure 112, spacers 122, and fin 108a, for example, to prevent structures from being processed during formation of source/drain regions 128. First liner 130 may, for example, be formed on fin 108a of FIG. 2a, dummy gate semiconductor structure 112, and spacers 122 during the formation of source/drain regions 128 of 108b of FIG. 2b. First liner 130 may be formed on initial structure 100 of FIG. 2, for example, by conformal deposition and/or any other now known or later developed semiconductor fabrication process for forming a liner layer. First liner 130 may include, for example, silicon nitride (SiN), and/or any other now known or later developed liner materials.

As shown in FIG. 3b, a portion 134 (in phantom) of first liner 130 may be removed to re-expose surfaces 126 (in phantom) of fin 108b so that source/drain regions 128 may be formed therein. During removal, portion 134 (in phantom) of first liner 130 positioned on dummy gate structure 112 and fin 108b may also be removed. Portion 134 (in phantom) may be removed by any now known or later developed semiconductor fabrication techniques. For example, portion 134 (in phantom) may be removed, by RIE, using a mask (not shown).

Once surfaces 126 (in phantom) of fin 108b have been re-exposed, openings 136 (i.e., recessed fin regions) may, for example, be formed in fin 108b at those surfaces. Openings 136 may be formed, for example, for forming source/drain regions 128 therein. Openings 136 may be formed in fin 108b by any now known or later developed semiconductor fabrication techniques for forming an opening in a fin of a FET. For example, openings 136 may be formed by selective Si recess RIE, and/or any other now known or later developed semiconductor fabrication techniques for forming openings in a fin.

Source/drain regions 128 may be formed in openings 136 in fin 108b. Source/drain regions 128 may be formed in fin 108b to allow current flow between the regions for a PFET structure formed therefrom. Source/drain regions 128 may be formed within openings 136 of 108b by conventional semiconductor fabrication techniques for forming a source/drain region. For example, source/drain regions 128 may be formed in openings 136 by epitaxial growth and/or selective deposition on the semiconductor materials of 108b. As shown in FIG. 3b, source/drain regions 128 may include raised source/drain regions, i.e., upper surface 132 of source/drain regions 128 may partially extend above an uppermost surface 138 of fin 108b.

Source/drain regions 128 may, for example, be formed with in-situ P-type doping during epitaxial growth or by implanting P-type dopants after epitaxial growth, and thus may be referred to as “P-type source/drain regions.” P-type source/drain regions 128 may be formed to establish a PFET structure in PFET region 104 for a set of complimentary PFET and NFET. A P-type source/drain region may be formed by forming positively charged particles in the source/drain region by doping. For example, a P-type is element is introduced to the semiconductor to generate free hole (by “accepting” electron from semiconductor atom and “releasing” hole at the same time). The P-type dopant or acceptor atom must have one valence electron less than the host semiconductor. P-type dopants may include but are not limited to, for example, boron (B), indium (In) and gallium (Ga). Source/drain regions 128 may include any now known or later developed material for a P-type source/drain region for a PFET. For example, source/drain regions 128 may include silicon germanium and/or any other now known or later developed stressor for generating a compressive stress in the channel of the PFET to enhance the mobility of the holes created by the P-type dopant.

As shown in FIG. 3b, and as may be desirable for a PFET structure, forming source/drain regions 128 in PFET region 104 as described herein may, for example, result in little if any gouging of the source drain region. For example, an uppermost surface 132 of source/drain regions 128 may be substantially planar which may allow for stress to be maintained in the source/drain regions for a PFET structure.

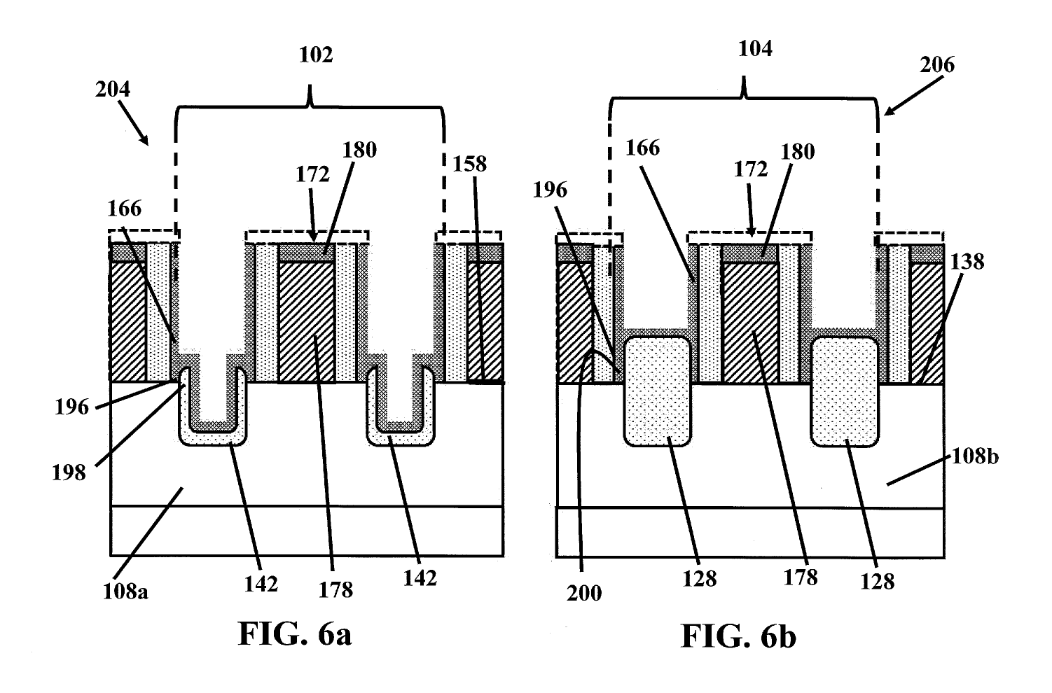

Source/drain regions 128 may also be formed, for example, to include an upper region 140 with a high percentage of germanium (Ge). For example, upper region 140 may include at least 60% germanium (Ge). As used herein, a “high percent” of germanium may include, for example, approximately 60% of germanium (Ge) to approximately 100% of germanium (Ge). Upper region 140 of source/drain regions 128 may include a depth D1 of approximately 1 nanometer to approximately 10 nanometers. The remainder of source/drain regions 128 may include, for example, a germanium percentage of approximately 20% germanium (Ge) to approximately 60% Germanium (Ge). Forming upper region 140 to include a high percentage of germanium may, for example, provide a relatively low electrical resistance between set of contact structures 174, 176 (see FIG. 6b) and source/drain regions 128 as will be described further herein with respect to FIG. 6b.

Turning to FIGS. 4a and 4b, FIG. 4a shows forming source/drain regions 142 of fin 108a in NFET region 102, according to embodiments of the disclosure. As discussed above with respect to source/drain regions 128 of fin 108b, source/drain regions 142 may be formed in fin 108a separately from source/drain regions 128. Forming source/drain regions 142 separately may allow for different processing of the source/drain regions including non-uniform gouging. As shown in FIG. 4b, PFET region 104 may not be further processed during formation of source/drain regions 142.

As shown in FIGS. 4a and 4b, before forming source/drain regions 142, first liner 130 (see FIGS. 3a and 3b) may be removed and a second liner 146 may be formed on source/drain regions 128, dummy gate semiconductor structure 112, and spacers 122. First liner 130 may be removed, for example, by wet etching and/or any other now known or later developed semiconductor fabrication techniques for removing a liner. Second liner 146 may be formed by any now known or later developed semiconductor fabrication techniques for forming a liner. For example, second liner 146 may be formed by deposition. Second liner 146 may include, for example, silicon nitride (SiN), and/or any other now known or later developed liner materials.

A portion 148 (in phantom) of second liner 146 may be removed, for example, to re-expose surfaces 124 (in phantom) of fin 108a for forming source/drain regions 142. As shown in FIG. 4a, during removal, portion 148 (in phantom) of second liner 146 positioned above dummy gate structure 112 and fin 108a may also be removed. Portions 148 (in phantom) may be removed by any now known or later developed semiconductor fabrication techniques for removing a liner material, for example, RIE using a mask (not shown).

As shown in FIG. 4a, openings 150 may be formed at re-exposed surfaces 124 (in phantom) of fin 108a for formation of source/drain regions 142 therein. Openings 150 may be formed by any now known or later developed semiconductor fabrication techniques for forming an opening in a fin of a FET. For example, openings 150 may be formed by a selective silicon (Si) recess RIE process, and/or any other now known or later developed semiconductor fabrication processes for forming an opening in a fin.

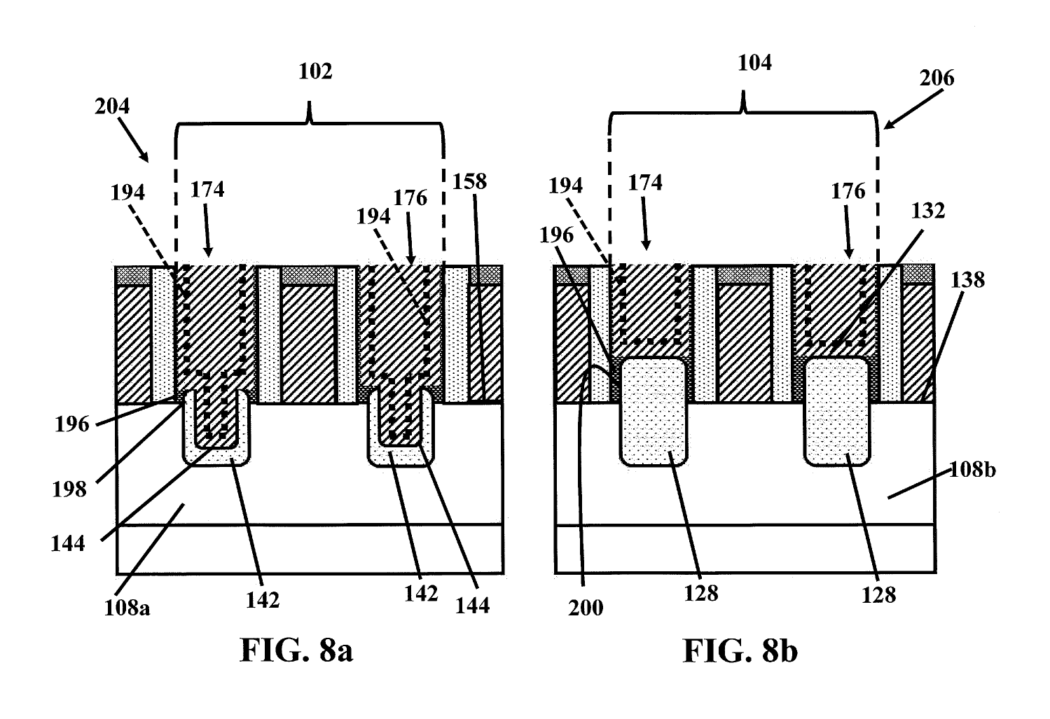

As shown in FIG. 4a, source drain regions 142 may be formed in openings 150 in fin 108a. Source/drain regions 142 may be formed in fin 108a to allow current flow between the regions for an NFET structure formed therefrom. Source/drain region 142 may be formed, for example, by epitaxial growth and/or selective deposition on semiconductor materials. In contrast to conventional source/drain region formation and gouging, source/drain regions 142 may be formed by reducing the total amount of epi growth such that opening 150 is less than completely filled with source/drain regions 142. For example, source/drain regions 142 may be conformally grown on the sidewalls of openings 150. Forming source/drain regions 142 as described herein may, for example, result in openings 144 being formed within source/drain regions 142. Openings 144 may be formed, for example, for subsequently forming contact structures therein as will be described below with respect to FIGS. 8a and 8b. Epitaxial growth of source/drain regions generally occurs at a faster rate in the x-direction as defined in FIG. 4a. As shown in FIG. 4a, as a result of the faster growth rate in the x-direction, thickness T1 of a bottommost portion 152 of source/drain regions 142 may be greater than thickness T2 of sidewalls 154 of source/drain regions 142. Due to both the overall reduced epi growth of the epitaxial growth process and the faster growth in the x-direction source/drain regions 142 my therefore include the substantially U-shaped cross-sectional geometry shown in FIG. 4a.

Source/drain regions 142 may be formed with in-situ N-type doping during epitaxial growth or by implanting N-type dopants after epitaxial growth, and thus may be described herein as “N-type source/drain regions.” N-type source/drain regions 142 may be formed to establish an NFET structure in NFET region 102 for a set of complimentary PFET and NFET. An N-type source/drain region may be formed by forming negatively charged electrons in the source/drain region by doping. For example, an N-type is element is introduced to the semiconductor to generate free electron (by “donating” electron to semiconductor). The N-type dopant must have one more valance electron than the semiconductor. Common donors in silicon (Si) may include: phosphorous (P), arsenic (As), antimony (Sb) and in gallium arsenic (GaAs): sulphur (S), selenium (Se), tin (Sn), silicon (Si), and carbon (C). N-type dopants may include, for example, phosphorous (P), arsenic (As), antimony (Sb). Source/drain regions 142 may include, for example, silicon phosphorus (SiP), and/or any other now known or later developed material for forming an N-type source/drain region.

As may be desirable for an NFET structure, forming source/drain regions 142 in NFET region 102 as described herein may, for example, allow for subsequently formed contact structures to be formed deeper within the source/drain regions. For example, a bottommost surface 156 of opening 144 may be positioned lower than an uppermost surface 158 of fin 108a. A contact structure may therefore be formed in source/drain region 142 extending lower than uppermost surface 158 which may, for example, decrease the stress therein. Additionally, opening 144 may provide an increase in the potential interface area between source drain region 142 and a contact structure to be formed subsequently therein. As described above, increasing the interface area between the source/drain region and a contact structure may decrease the resistance at the contact structure which may be beneficial to the performance of the integrated circuit (IC) structure.

Turning to FIGS. 4a and 4b together, in contrast to conventional complimentary NFETs and PFETs, forming source/drain regions 142 in NFET region 102 and source/drain regions 128 in PFET region 104 may allow for non-uniform gouging of the source/drain regions. For example, source/drain regions 142 include openings 144 with a bottommost surface 158 positioned lower than uppermost surface 132 of source/drain regions 128. In contrast to conventional uniform gouging, non-uniform gouging of source/drain regions 128, 142 may, for example, accommodate the different desirable gouging extents for both the NFET and PFET structures.

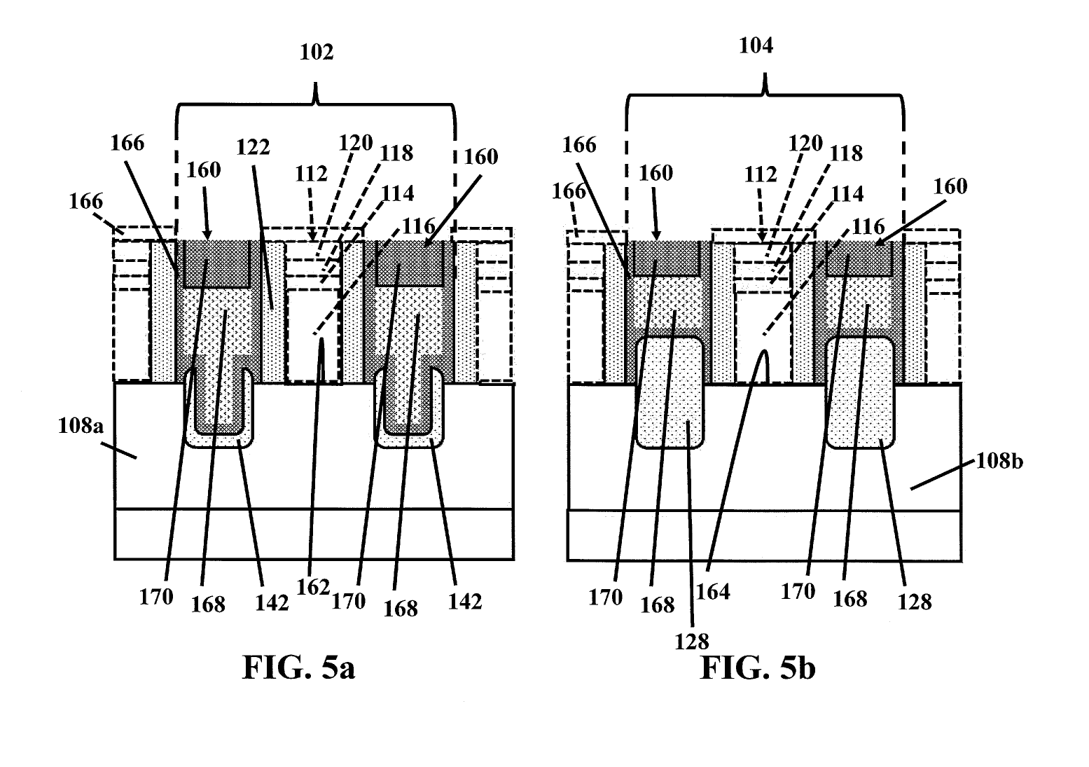

FIGS. 5a and 5b show forming a set of dummy contact structures 160 on source/drain regions 128, 142 in PFET region 104 and NFET region 102, respectively, and removing dummy gate semiconductor structure 112 (in phantom), according to embodiments of the disclosure. Set of dummy contact structures 160 may be formed, for example, to protect source/drain regions 128, 142 during a subsequent removal of dummy gate semiconductor structure 112, and during later contact structure formation. Dummy gate body structure 116 may be removed, for example, for subsequent formation of a conductive replacement metal gate structure in its place to form functioning transistors. As will be described herein, portions of dummy gate semiconductor structure 112 (e.g., second gate hard mask 120, and dummy gate cap 118) may be removed during the formation of set of dummy contact structures 160.

Before forming dummy contact structures 160, second liner 146 (see FIGS. 4a and 4b) may be removed from source/drain regions 128, dummy gate semiconductor structure 112 (in phantom), and spacers 122. Second liner 146 (see FIGS. 4a and 4b) may be removed, for example, by wet etching, and/or any other now known or later developed semiconductor fabrication processes for removing a liner.

After second liner 146 (see FIGS. 4a and 4b) has been removed, a third liner 166 may be formed, for example, as a protective layer for preventing pre-mature processing of structures therebelow during intermediate processing steps. Third liner 166 may be formed, for example, on source/drain regions 128, 142, dummy gate semiconductor structure 112 and spacers 122 after removing second liner 146 (see FIGS. 4a and 4b) and before forming set of dummy contact structures 160. Third liner 166 may be formed by conventional semiconductor fabrication techniques such as, for example, conformal deposition. Third liner 166 may include silicon nitride (SiN), silicon oxide (SiO₂), and/or any other now known or later developed liner materials.

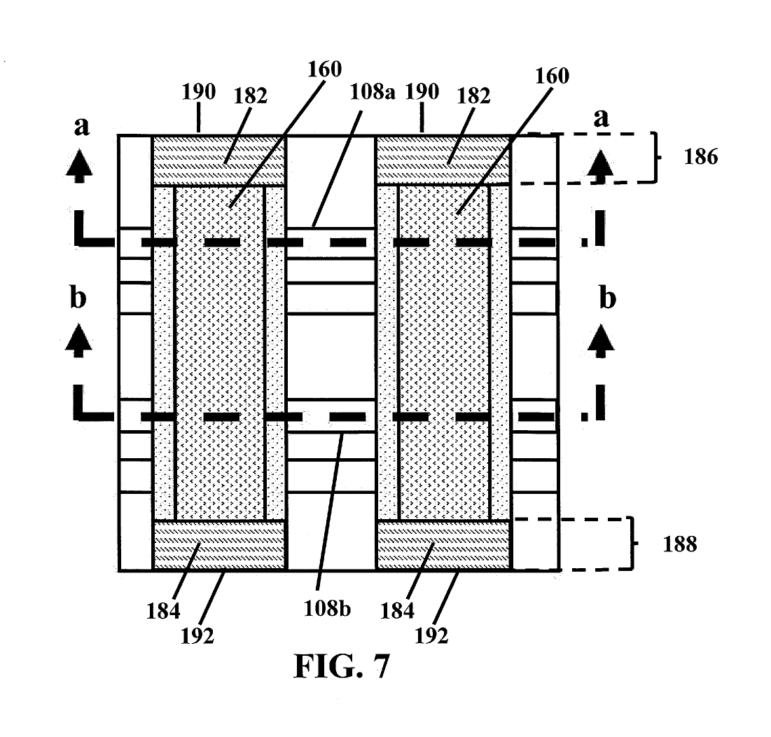

After third liner 166 has been formed, dummy contact structures 160 may be formed, for example, to prevent further processing of source/drain regions 128, 142 during the removal of dummy gate semiconductor structure 112 and later formation of contact structures. Set of dummy contact structures 160 may be formed on third liner 166 and adjacent to spacers 122. Turning briefly to FIG. 7, set of dummy contact structures 160 may traverse fins 108a, 108b into the plane of FIGS. 5a and 5b. Returning to FIGS. 5a and 5b, set of dummy contact structures 160 may include, for example, a sacrificial material layer 168 positioned on third liner 166, and a dummy contact cap 170 above the sacrificial material. Dummy contact cap 170 may, for example, act as an etch stop and/or planarization stop layer during the removal of dummy gate semiconductor structure 112.

Sacrificial material 168 may be formed on third liner 166 by any now known or later developed semiconductor fabrication techniques for forming sacrificial material on a liner. For example, sacrificial material 168 may be formed by deposition, planarization and etching. Second gate hard mask 120 (in phantom) of dummy gate semiconductor structure 112 (in phantom) may act as a planarization stop layer during the planarization of sacrificial material 168. Additionally, dummy gate cap 118 (in phantom) of dummy gate semiconductor structure 112 (in phantom) may act as an etch stop layer during etching of sacrificial material 168 after planarization. Second gate hard mask 120 (in phantom) of dummy gate semiconductor structure 112 (in phantom) may therefore, for example, be removed during formation of sacrificial material 168 of set of dummy contact structures 160. Sacrificial material 168 may include, for example, amorphous silicon (a-Si), and/or any other now known or later developed dummy contact sacrificial material.

Dummy contact cap 170 of dummy contact structures 160 may be formed on sacrificial material 168 by any now known or later developed semiconductor fabrication techniques for forming a cap layer. For example, cap 170 may be formed by deposition and planarization. Dummy contact cap 170 may include silicon nitride (SiN), silicon oxide (SiO₂), and/or any other now known or later developed cap materials. During planarization of dummy contact cap 170 of set of dummy contact structures 160, the portion (in phantom) of third liner 166 above dummy gate semiconductor structure 112 (in phantom) and dummy gate cap 118 (in phantom) of dummy gate semiconductor structure 112 (in phantom) may also be removed by the planarization to expose first gate hard mask 114 (in phantom). First gate hard mask 114 (in phantom) may, for example, act as a planaraizing stop layer during formation of dummy contact cap 170.

After forming dummy contact cap 170 of set of dummy contact structures 160, the remainder of dummy gate semiconductor structure 112 (in phantom), may be removed. As discussed above, dummy gate semiconductor structure 112 (in phantom) may be removed to allow for a conductive replacement metal gate structure to be formed in its place for a functioning transistor. Removing dummy gate semiconductor structure 112 (in phantom) may, for example, expose surfaces 162, 164 of fins 108a, 108b, respectively, on which replacement metal gate structures may be subsequently formed. First gate hard mask 114 (in phantom) and dummy gate body 116 (in phantom), may be removed by any now known or later developed semiconductor fabrication techniques for removing a gate hard mask and dummy gate body material. For example, first gate hard mask 114 (in phantom) and dummy gate body 116 (in phantom) may be removed by wet etching. As also shown in FIGS. 5a and 5b, spacers 122 may remain on fins 108a, 108b after dummy gate semiconductor structure 112 (in phantom) is removed. Spacers 122 may remain to insulate and protect the subsequently formed replacement metal gate structure.

FIGS. 6a and 6b also show removing set of dummy contact structures 160 (see FIGS. 5a and 5b), and forming replacement metal gate structures on fins 108a, 108b to form functional transistor structures. As will be described herein, portions of set of dummy contact structures 160 (e.g., dummy contact cap 170) may be removed during the formation of replacement metal gate (RMG) structure 172.

As shown in FIGS. 6a and 6b, RMG structure 172 may be formed on fins 108a, 108b to form functional NFET 204 in NFET region 102 and PFET 206 in region 104, respectively. NFET 204 may include, for example, fin 108a, source/drain regions 142, and RMG structure 172 on fin 108a. PFET 206 may include, for example, fin 108b, source/drain regions 128, and RMG 172 over fin 108b. RMG 172 may be formed, for example, on exposed surfaces 162, 164 of fins 108a, 108b, respectively, between spacers 122. RMG structure 172 may include, for example, a RMG gate body 178, and a RMG gate cap 180. RMG gate cap 180 may, for example, act as an etch and/or planarization stop layer to protect RMG gate body 178. RMG gate body 178 may be formed, on surfaces 162, 164 of fins 108a, 108b, respectively, by any now known or later developed semiconductor fabrication techniques for forming a high-k metal gate on a fin. For example, RMG gate body 178 may be formed by deposition, planarizing, and etching. RMG gate body 178 may include, for example, hafnium oxide (HfO₂) as gate dielectric, titanium nitride (TiN), titanium carbide (TiC), titanium aluminide (TiAl), titanium nitride (TaN), etc. as work function metal (WFM), tungsten (W) and/or any other now known or later developed materials for a metal gate. RMG gate cap 180 may be formed on RMG gate body 178 by any now known or later developed semiconductor fabrication techniques for forming a cap on a metal gate. For example, RMG gate cap 180 may be formed by deposition and planarizing. RMG gate cap 180 may include, for example, silicon nitride (SiN) and/or any other now known or later developed metal gate structure cap materials. During the planarization of RMG gate cap 180, dummy contact cap 170 (see FIGS. 5a and 5b) of set of dummy contact structures 160 may be also be removed, exposing sacrificial material 168 (see FIGS. 5a and 5b).

Turning to FIG. 7, before removing the remainder of dummy contact structures 160, non-contact regions 182, 184 may be formed at edges 186, 188 of set of dummy contact structures 160, respectively. FIG. 7 shows a plan view of fins 108a, 108b, set of dummy contact structures 160 thereon, and non-contact regions 182, 184. Non-contact regions 182, 184 may be formed, for example, to isolate the contact structures and prevent formation of replacement contact structures 174, 176 (see FIGS. 8a and 8b) in regions which may result in shorting of the contact structures with other contact structures in the semiconductor device. Non-contact region 182, 184 may be formed, for example, by forming openings 190, 192 at edges 186, 188 of set of dummy contact structures 160, and forming dielectric materials such as SiN, SiCO, etc., therein. Openings 190, 192 may be formed, for example, by RIE. The dielectric material may be formed, for example, by deposition and planarization.

Returning to FIGS. 6a and 6b, sacrificial material 168 (see FIGS. 5a and 5b) of set of dummy contact structures 160 (see FIGS. 5a and 5b) may next be removed exposing third liner 166 (see FIGS. 5a and 5b). Sacrificial material 168 (see FIGS. 5a and 5b) may be removed, for example, by wet etching, and/or any other now known or later developed semiconductor fabrication technique for removing sacrificial material such as amorphous silicon (a-Si).

FIGS. 8a and 8b show forming a set of replacement contact structures 174, 176 to electrically connect source/drain regions 128, 142 to an overlying wiring layer.

Before forming the replacement contact structures, a portion 194 (in phantom) of third liner 166 (see FIGS. 5a and 5b) may be removed to expose openings 144 of source/drain regions 142, uppermost surfaces 132 of source/drain regions 128, and spacers 122. Exposing openings 144 and uppermost surfaces 132 may, for example, allow for replacement contact structures to be subsequently formed and electrically connected to the source/drain regions. The contact structures may connect the source/drain regions to a wiring structure of the IC structure thereabove. Portion 194 (in phantom) of third liner 166 (see FIGS. 5a and 5b) may be removed, for example, by wet etching and/or any other now known or later developed semiconductor fabrication techniques for removing the material of a liner structure. As shown in FIGS. 8a and 8b, after removing portion 192 (in phantom) of third liner 166 (see FIGS. 5a and 5b), portions 196 of the liner may remain adjacent to sides 198, 200 of source/drain regions 128, 142 positioned above upper surfaces 158, 138 of fins 108a, 108b, respectively. Portions 196 of third liner 166 (see FIGS. 5a and 5b) may, for example, protect portions of sidewalls 198, 200 of source/drain regions 128, 142.

Before replacement contact structures 174, 176 are formed, an initial metal liner (not show for purposes of simplicity) may be formed along the sidewalls of the contact structure before forming the conductive material therein. During formation of the initial metal liner, silicide may be formed on source/drain regions 128, 142. A barrier metal liner (also not shown for purposes of simplicity) may then be formed on the initial metal liner. The initial metal liner and barrier metal liner may be formed, for example, by deposition and/or any other now known or layer developed semiconductor fabrication techniques for forming a liner. The initial metal liner may include, for example, metals such as titanium (Ti), nickel (Ni), NiPt, etc., mixtures thereof, and/or any other now known or later developed metal liner material. The barrier metal liner may include, for example, titanium nitride (TiN) and/or any other now known or later developed barrier metal liner material.

Replacement contact structures 174, 176 may be formed to source/drain regions 128, 142. As discussed above, replacement contact structures 174, 176 may be formed to source/drain regions 128, 142 to electrically connect the source/drain regions to a wiring structure of the IC structure thereabove. For example, replacement contact structures 174, 176 may electrically connect source/drain regions 128, 142 to a metal wire (not shown) in a metal layer (not shown) positioned thereabove and electrically connected to a power source (not shown). Replacement contact structures 174, 176 may be formed, for example, in openings 144 of source/drain regions 142, on uppermost surfaces 138 of source/drain regions 128, and on spacers 122. Although not shown, replacement contact structures 174, 176 may traverse fins 108a, 108b into the page of FIGS. 8a and 8b. For example, FIG. 8a shows a cross-section of replacement contact structures 174, 176 along line a of FIG. 1, and FIG. 8b shows a cross-section of replacement contact structures 174, 176 along line b-b of FIG. 1.

Replacement contact structures 174, 176 may be formed, for example, by deposition, metallization and planarization, and/or any other now known or later developed semiconductor fabrication processes for forming a contact structure on source/drain regions. Replacement contact structures 174, 176 may include, for example, tungsten (W), cobalt (Co), ruthenium (Ru), and/or any other now known or later developed bulk metal materials for a contact structure. For example, replacement contact structures 174, 176, may be formed by plasma vapor deposition (PVD) and/or atomic later deposition (ALD) of titanium (Ti); thermal annealing of the titanium (Ti); ALD of titanium nitride (TiN) layer; ALD of tungsten (W); and chemical mechanical planarization (CMP) of the tungsten.

Turning to FIGS. 8a and 8b together, replacement contact structures 174, 176 may be formed to source/drain regions 128, 142 of PFET 206 and NFET 204, respectively. As discussed above with respect to FIGS. 4a and 4b, source/drain regions 128, 142 formed as described herein may be non-uniformly gouged compared to one another. As a result, in contrast to conventional contact structures formed on source/drain regions of complimentary NFETs and PFETs, replacement contact structures 174, 176 may be formed deeper within source/drain regions 142 compared to source/drain regions 128. For example, replacement contact structures 174, 176 may be formed within openings 144 of source/drain regions 142. Forming replacement contact structures 174, 176 within openings 144 may, for example, provide increased interface area between the contact structures and source/drain regions to decrease resistance at the interface. In contrast, replacement contact structures 174, 176 may be formed to contact uppermost surfaces 132 of source/drain regions 128 rather than within source/drain regions 128. Forming contact structures 174, 176 to uppermost surface 132 of source/drain regions 128, for example, maintain the stress within the source/drain regions as may be desirable for PFET 206. Additionally, replacement contact structures 174, 176 may be formed directly on upper region 140 of source/drain regions 128 of PFET 104 including a high percentage of germanium. Replacement contact structures 174, 176 interfacing with a high percentage germanium region of source/drain region 128 may, for example, further decrease the resistance at the interface as may be desirable for performance of the PFET. Replacement contact structures 174, 176 formed to source/drain regions 128, 142 may therefore accommodate the differing desirable amounts of source/drain region gouging for a PFET and NFET structure.

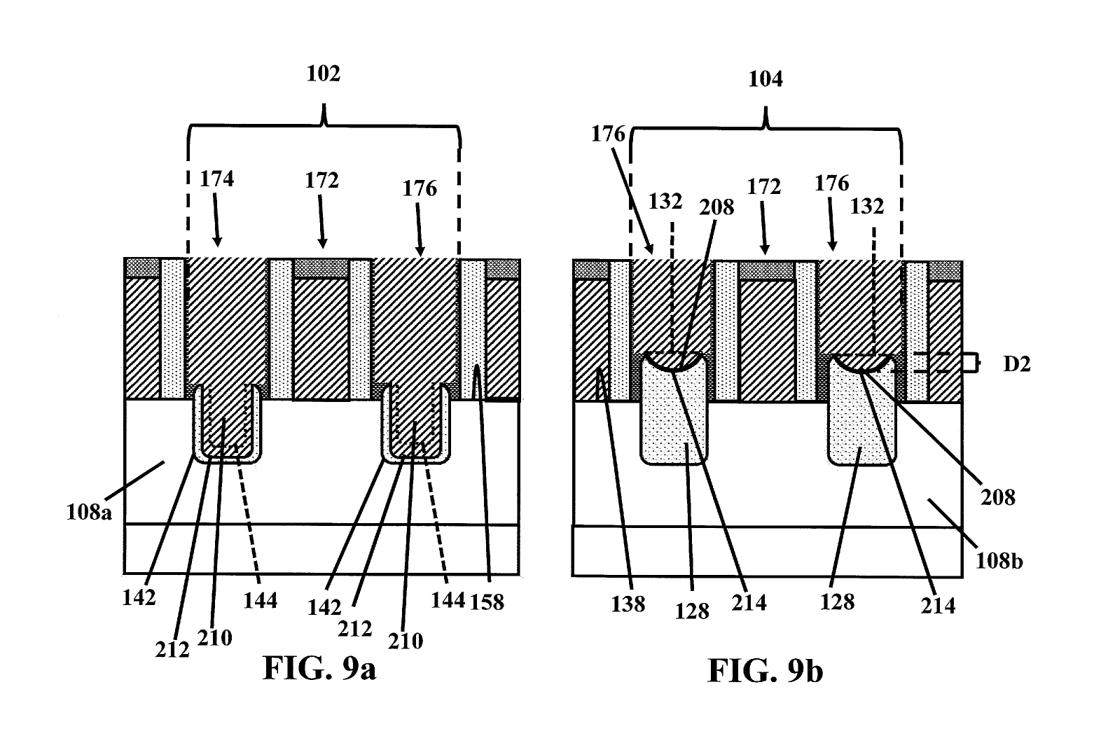

In contrast to FIGS. 8a and 8b, FIGS. 9a and 9b show further gouging source/drain regions 128, 142 (see FIGS. 4a and 4b) after removing portions 194 (in phantom) of third liner 166 (see FIGS. 8a and 8b), and before forming set of replacement contact structures 174, 176. Further gouging source/drain regions 128, 142 may, for example, increase the interface area between source/drain regions 128 and contact structures subsequently formed thereto and therefore decrease electrical resistance at the interface.

Further gouging source/drain regions 128, 142 may be performed, for example, after the removal of portion 194 of third liner 166 (see FIGS. 8a and 8b) re-exposing of openings 144 and upper surfaces 132, as described above with respect to FIGS. 8a and 8b. For example, further gouging source/drain regions 128, 142 may include forming openings 208, 210 in source/drain regions 128, 142, respectively.

FIG. 9a shows forming openings 210, for example, in source/drain regions 142 of fin 108a of NFET region 102. After portions 194 (in phantom) of third liner 166 (see FIGS. 8a and 8b) are removed as described above with respect to FIGS. 8a and 8b, openings 144 of source/drain regions 142 may be re-exposed. Openings 210 may be formed, for example, at re-exposed openings 144. Openings 210 may be formed by any now known or later developed semiconductor fabrication techniques for forming an opening in a source/drain region. For example, openings 210 may be formed by RIE. As may be desirable for an NFET structure in NFET region 102, further gouging source/drain regions 142 may increase the interface area for a contact structure formed subsequently thereto and therefore decrease the electrical resistance at the interface

As shown in FIG. 9b, openings 208 may be formed, for example, in source/drain regions 128 in PFET region 104. After portions 194 (in phantom) of third liner 166 (see FIGS. 8a and 8b) are removed as described above with respect to FIGS. 8a and 8b, upper surfaces 132 of source/drain regions 128 may be re-exposed. Openings 208 may be formed, for example, at re-exposed upper surfaces 128. Openings 208 may be formed by any now known or later developed semiconductor fabrication techniques for forming an opening in a source/drain region. For example, openings 208 may be formed by selective RIE. A depth D2 of opening 208 may be small enough that the stress within source/drain regions 128 is not reduced so much as to render the semiconductor device inoperable. Gouging source/drain regions 128 may, for example, increase the interface area for a contact structure formed subsequently thereto, and therefore decrease electrical resistance at the interface.

Turning to FIGS. 9a and 9b together, forming openings 208, 210 may, for example, result in source/drain regions 128, 142 continuing to have non-uniform gouges formed therein. For example, a bottommost portion 214 of openings 208 of source/drain regions 128 may be positioned higher than a bottommost portion 212 of openings 210 of source/drain regions 142. Forming non-uniform source/drain regions 128, 142 as described herein may, for example, allow for source/drain region gouging which accommodates the differing desirable amounts of gouging for each of the NFET and PFET structures.

Before replacement contact structures 174, 176 are formed, an initial metal liner (not show for purposes of simplicity) may be formed along the sidewalls of the contact structure before forming the conductive material therein. During formation of the initial metal liner, silicide may be formed on source/drain regions 128, 142. A barrier metal liner (also not shown for purposes of simplicity) may then be formed on the initial metal liner. The initial metal liner and barrier metal liner may be formed, for example, by deposition and/or any other now known or layer developed semiconductor fabrication techniques for forming a liner. The initial metal liner may include, for example, metals such as titanium (Ti), nickel (Ni), NiPt, etc., mixtures thereof, and/or any other now known or later developed metal liner material. The barrier metal liner may include, for example, titanium nitride (TiN) and/or any other now known or later developed barrier metal liner material.

Replacement contact structures 174, 176 may be formed to source/drain regions 128, 142 for similar reasons as those set forth above with respect to FIGS. 8a and 8b. For example, replacement contact structures 174, 176 may electrically connect source/drain regions 128, 142 to an overlying wiring structure (not shown) of the integrated circuit structure. As shown in FIGS. 9a and 9b, replacement contact structures 174, 176 may be formed in openings 208, 210 of source/drain regions 128, 142, respectively, and on the sides of spacers 122 after forming openings 208, 210. Although not shown, replacement contact structures 174, 176 may, for example, traverse fins 108a and 108b into and out of the page of FIGS. 9a and 9b. Replacement contact structures 174, 176 may be formed, for example, by deposition, metallization and planarization, and/or any other now known or later developed semiconductor fabrication processes for forming a contact structure on source/drain region. Replacement contact structures 174, 176 may include, for example, tungsten (W), cobalt (Co), ruthenium (Ru), and/or any other now known or later developed materials for a contact structure. For example, replacement contact structures 174, 176 may be formed by, plasma vapor deposition (PVD) and/or atomic later deposition (ALD) of titanium (Ti); thermal annealing of the titanium (Ti); ALD of titanium nitride (TiN) layer; ALD of tungsten (W); and chemical mechanical planarization (CMP) of the tungsten.

As shown in FIGS. 9a and 9b, in contrast to FIGS. 8a and 8b, forming replacement contact structures 174, 176 in openings 208, 210 may allow the contact structures to be formed deeper within source/drain regions 128, 142 than openings 144 (in phantom) and upper surfaces 132 (see FIG. 6b).

As also shown in FIG. 9a, bottommost portion 212 of openings 210 may be positioned lower than a bottommost portion of openings 144 (in phantom) which may allow for replacement contact structures 174, 176 to be formed deeper within source/drain regions 142. Forming replacement contact structures 174, 176 within openings 210 deeper within source/drain regions 142 may, for example, further reduce the stress within the source/drain regions, as may be desirable for an NFET within NFET region 102. Openings 210 may also, for example, increase the interface area between the contact structures and the source/drain regions which may decrease the electrical resistance at the interface.

As shown in FIG. 9b, for example, a bottommost portion 214 of openings 208 may be positioned lower than upper surfaces 132 (in phantom) which may allow for replacement contact structures 174, 176 to be formed within source/drain regions 128. Forming replacement contact structures 174, 176 within openings 208 may, for example, increase the interface area between source/drain regions 128 and replacement contact structures 174, 176. Additionally, openings 208 may be shallow enough so as to not reduce the stress within the source/drain regions to render the semiconductor device inoperable. For example, the stress within source/drain regions 128 before forming openings 208 may be approximately 0.5 gigapascals (GPa) to approximately 2.5 GPa, and the stress within source/drain regions 128 after forming openings 208 and replacement contact structures 174, 176 therein, may be approximately 0.45 GPa to approximately 2.25 GPa. Forming replacement contact structures 174, 176 within openings 208 of source/drain regions 128 of PFET region 104 may also, for example, result in decreased electrical resistance due to the increased interface area formed by openings 208.

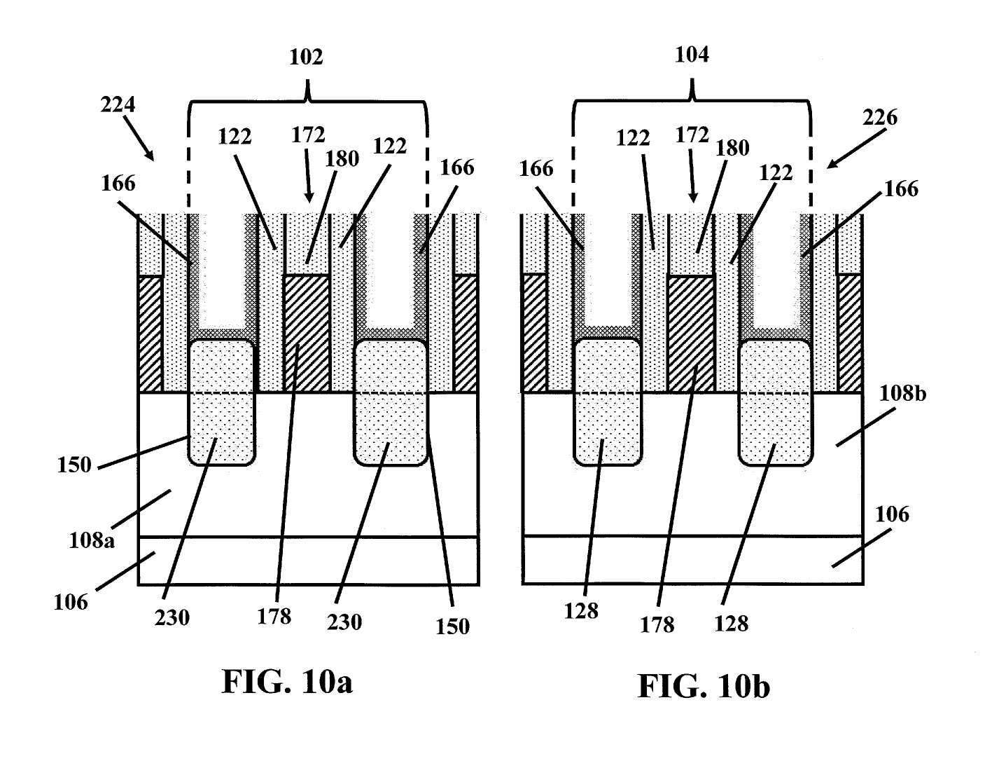

Turning to FIGS. 10-13, in contrast to FIGS. 8 and 9, FIGS. 10-13 show forming non-uniformly gouged, raised NFET and PFET source/drain regions using a mask to protect fin 108b in PFET region 104 during processing of fin 108a in NFET region 102.

Before proceeding to FIGS. 10a and 10b, it is noted that FIGS. 10a and 10b illustrates the result of multiple intermediate processes being applied to other structures, e.g., one or more structures illustrated in a preceding illustration. Such depiction of multiple process steps are provided relative to the implementation of multiple processing techniques discussed herein relative to FIGS. 1-7. It is therefore understood that the various techniques described herein relative to one or more or FIGS. 1-7 may be applied and depicted together in FIGS. 10a and 10b, and that the various processing techniques described herein may be combined and/or substituted where appropriate without departing from the underlying technical concepts and characteristics of the present disclosure. It is again emphasized that the processes discussed herein and shown in the accompanying FIGS. 1-7 and FIG. 10a and 10b reflect a similar or identical set of processing concepts with possible variances in implementation, discussed herein.

FIGS. 10a and 10b show NFET 224 and PFET 226 for forming non-uniformly gouged source/drain regions using a mask, according to embodiments of the disclosure

Turning to FIG. 10a, NFET 224 is substantially similar to NFET 204 as depicted and described in FIG. 6a, with the exception of source/drain regions 142 (see FIG. 6a) of NFET 204. For example, as opposed to the embodiments discussed above with respect to FIGS. 1-7 in which source/drain regions 142 (see FIG. 4a) are formed to partially fill openings 150 in fin 108a, embodiments of the disclosure may include forming raised source/drain regions 230 in openings 150 of fin 108a for NFET 224.

NFET 224 may include, for example, fin 108a positioned on substrate 106. Fin 108a and substrate 106 may be formed by the same processes and materials as structures with like numbering as set forth above in FIGS. 1-6.

NFET 224 may also include, for example, raised source/drain regions 230 formed in fin 108a. Raised source/drain regions 230 may be formed, for example, to be subsequently gouged while source/drain regions 128 are protected by a mask. Raised source/drain regions 230 may be formed, for example, after a dummy gate structure (not shown, see also dummy gate structure 112 of FIG. 2a) is formed on fin 108a. Source/drain regions 230 may be formed by conventional semiconductor fabrication processes for forming raised source/drain regions. Source/drain regions 230 may be formed in openings 150 of fin 108a with in-situ N-type dopants during epitaxial growth or by implanting N-type dopants after epitaxial growth, and thus may be described herein as an “N-type source/drain regions.” In contrast to source/drain regions 142, source/drain regions 230 may be formed to fill openings 150 of fin 108a. N-type source/drain regions 230 may be formed to establish an NFET structure in NFET region 102 for a set of complimentary PFET and NFET. An N-type source/drain region may be formed by forming negatively charged electrons in the source/drain region by doping. For example, an N-type is element is introduced to the semiconductor to generate free electron (by “donating” electron to semiconductor). The N-type dopant must have one more valance electron than the semiconductor. Common donors in silicon (Si) may include: phosphorous (P), arsenic (As), antimony (Sb) and in gallium arsenic (GaAs): sulphur (S), selenium (Se), tin (Sn), silicon (Si), and carbon (C). N-type dopants may include, for example, phosphorous (P), arsenic (As), antimony (Sb). Source/drain regions 230 may include, for example, silicon phosphorus (SiP), and/or any other now known or later developed material for forming an N-type source/drain region.

As also shown in FIG. 10a, NFET 224 may also include replacement metal gate (RMG) structure 172 formed on fin 108a and positioned between raised source/drain regions 230. RMG 172 may include gate body 178 and cap 180 positioned thereon. RMG 172 may be formed on fin 108a after liner 166, spacers 122 and dummy contact structures (not shown, see also dummy contact structures 160 of FIG. 5a) positioned between spacers 122 are formed on raised source/drain regions 230 to protect the source/drain regions from further processing. As shown in FIG. 10a and as described above with respect to FIG. 6a, the dummy contact structures (not shown) may be removed after RMG 172 is formed. As also shown in FIG. 10a, spacers 122 may remain on fin 108a, and liner 166 may remain on source/drain regions 230 after removal of the dummy contact structure (not shown). Spacers 122, RMG 172 including gate body 178 and cap 180, and liner 166 may be formed by similar processes and materials as similarly numbered structures as set forth in FIGS. 1-7.

Turning to FIG. 10b, PFET 226 is substantially similar to PFET 206 as depicted and described in FIG. 6b. PFET 226 may include, for example, fin 108b positioned on substrate 106. PFET 226 may also include, for example, raised source/drain regions 128 formed in fin 108b. RMG 172 including gate body 178 and cap 180, may also be formed on fin 108b and positioned between raised source/drain regions 128. Spacers 122 may be positioned on fin 108b on either side of RMG 172 and also positioned between raised source/drain regions 128. Liner 166 may also be positioned on raised source/drain region 128 and the sidewalls of spacers 122. Fin 108b, substrate 106, raised source/drain regions 128, RMG 172 and its components, spacers 122, and liner 166 may be formed by the same processes and materials as structures with like numbering as set forth above in FIGS. 1-6.

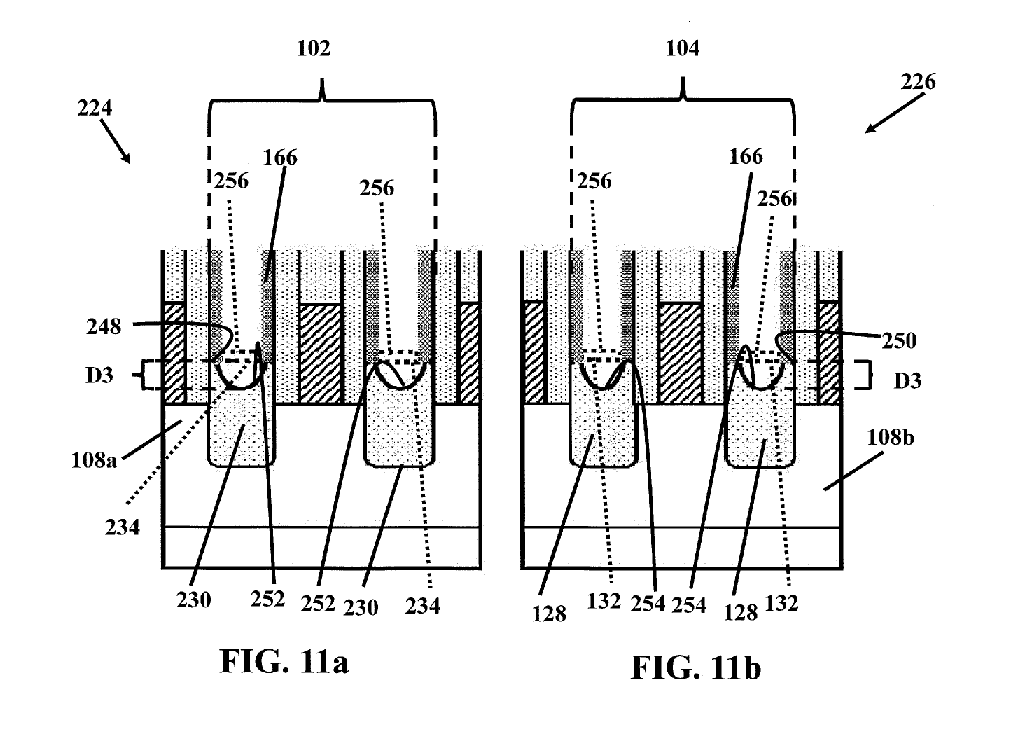

In contrast to FIGS. 8a and 8b where replacement contact structures are formed to the source drain regions after dummy contact structures are removed, FIGS. 11a and 11b show uniformly gouging source/drain regions 230, 128 forming openings 252, 254, respectively. Openings 252, 254 may include, for example, a depth D3 of approximately 10 nanometers to approximately 25 nanometers, which may be desirable for maintaining the stress in source/drain regions 128 of PFET 226 without rendering the semiconductor structure inoperable.

Before forming openings 252, 254, a portion 256 (in phantom) of liner 166 may be removed, for example, to re-expose upper surfaces 234, 132 (phantom) of source/drain regions 230, 128, respectively. Portion 256 (in phantom) of liner 166 may be removed by any now known or later developed semiconductor fabrication techniques for forming and removing a liner. For example, portion 256 (in phantom) may be removed by RIE, using a mask (not shown).

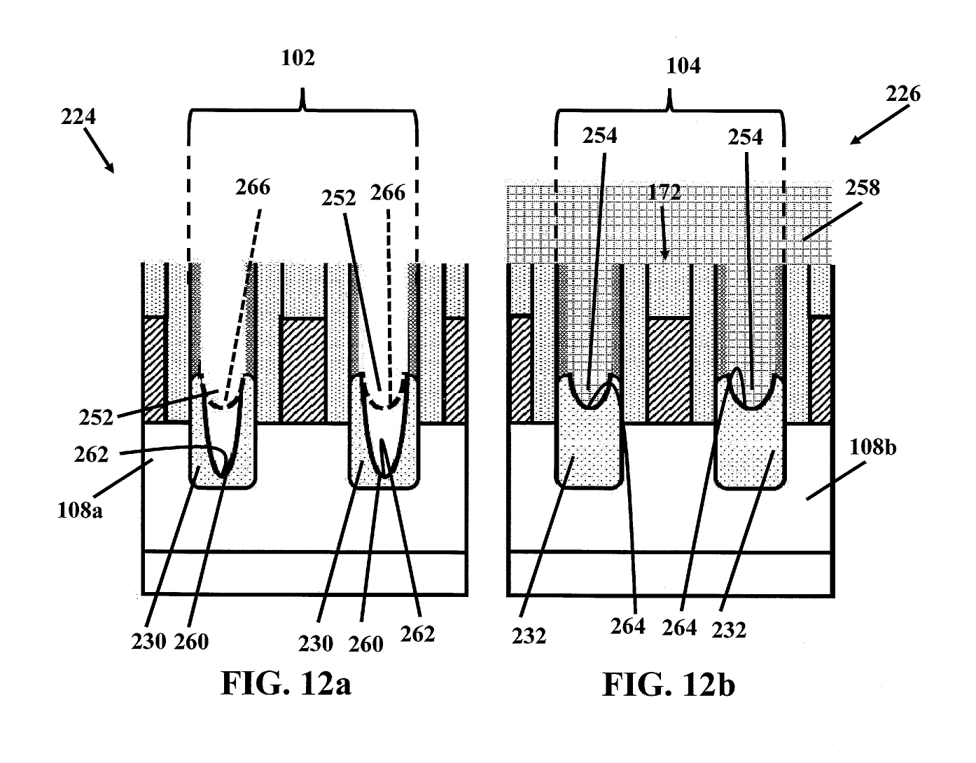

Openings 252, 254 may be formed at re-exposed upper surfaces 234, 132, respectively, of source/drain regions 230, 128, respectively by any other now known or later developed semiconductor fabrication techniques for forming an opening in a source/drain region. For example, openings 252, 254 may be formed, by RIE using a mask (not shown). As shown in FIGS. 12a and 12b, liner 166 may continue to contact portions 248, 250 of upper surfaces 234, 132 after openings 252, 254 are formed.

FIGS. 12a and 12b show non-uniformly gouging source/drain regions 230, 232, according to embodiments of the disclosure.

FIG. 12b shows forming a mask 258 on PFET region 104 including source/drain regions 128 and the portion of gate structure 172 therein. Mask 258 may be formed, for example, to protect the structures in PFET region 104 from being further processed during formation of deeper openings 260 in source/drain regions 230 as shown in FIG. 12a.

Mask 258 may be formed in PFET region 104 including source/drain regions 128 and the portion of gate structure 172 therein by any other now known or later developed semiconductor fabrication techniques for forming a mask on a semiconductor structures. For example, mask 258 may be formed by deposition, patterning and planarizing. Mask 258 may include, an organic planarizing layer (OPL) and/or any other now known or later developed semiconductor materials for a mask.

FIG. 12a shows forming deeper openings 260 at openings 252 of source/drain regions 230 of fin 108a. Forming openings 260 may result, for example, in non-uniform gouging in source/drain regions 230, 128 between NFET 224 and PFET 226, respectively.

Openings 260 may be formed in source/drain regions 230 at exposed surfaces 266 (in phantom) of openings 252 (in phantom). Openings 260 may be formed by any now known or later developed semiconductor fabrication technique for forming a further opening in a source/drain region. For example, openings 260 may be formed by etching exposed surfaces 266. As shown in FIG. 12a forming openings 260 may result in source/drain regions 230 including a substantially U-shaped cross-sectional geometry.

FIGS. 12a and 12b together show the non-uniform gouging of source drain regions 230, 128, respectively. For example, as shown in FIGS. 12a and 12b a bottommost portion 262 of openings 260 in source/drain regions 230 may be positioned lower than a bottommost portion 264 of openings 254 of source/drain regions 128. Forming non-uniform openings between source/drain regions of complimentary NFET 224 and PFET 226 may, for example, accommodate the different desirable amounts of source/drain gouging associated with the NFET and PFET structures. For example, forming openings 254 in source/drain regions 128 of PFET 226 may increase the interface area between the source/drain regions and a contact structure subsequently formed thereto. Increasing the interface area may, for example, decrease the electrical resistance at the interface which may be beneficial to the performance of the semiconductor structure. Forming openings 254 in source/drain regions 128 of PFET 226 at a shallower depth than openings 260 formed in source/drain regions 230 may, for example, continue to maintain the stress in the source/drain regions as may be desirable for a PFET structure. In contrast, forming openings 260 in source/drain regions 230 in NFET 226 may, for example, allow for subsequently formed contact structures to be formed deeper within the source/drain regions. Forming contact structures deeper within source/drain regions 230 may, for example, increase the interface area between the contact structures and the source/drain regions and therefore decrease the resistance at the interface.

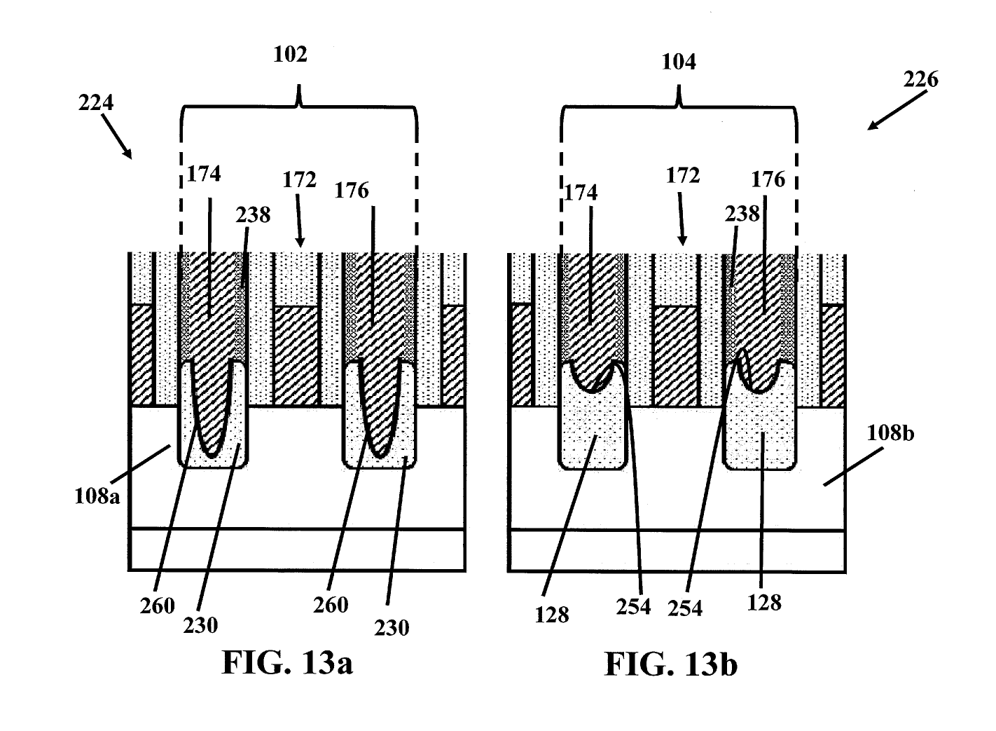

FIGS. 13a and 13b show removing mask 258 (see FIG. 12b) from source/drain regions 128 and gate structure 172, and forming set of contact structures 174, 176 to source/drain regions 230, 128. Contact structures 174, 176 may be formed, for example, to electrically connect source/drain regions 230, 128 to a wiring layer (not shown) of the semiconductor structure. For example, contact structures 174, 176 may electrically connect source/drain regions 230, 128 to a metal wire (not shown) in a metal layer thereabove (not shown) which may be electrically connected to a power source (not shown).

Mask 258 may be removed by conventional semiconductor fabrication techniques for removing a mask structure. For example, mask 258 may be removed by ashing.

Before forming replacement contact structures 174, 176 on source/drain regions 230, 128 a silicide region (not shown for purposes of simplicity) may be formed on source/drain regions 230, 128. The silicide regions may be formed for example, by performing an in-situ pre-clean; depositing a metal such as titanium, nickel, cobalt, etc.; annealing the deposited metal; and removing any unreacted metal. Additionally, before replacement contact structures 174, 176 are formed, a refractory metal liner (not show) may also be formed along the sidewalls of the contact structure before forming the conductive material therein. The refractory metal liner may be formed, for example, by deposition and/or any other now known or layer developed semiconductor fabrication techniques for forming a liner. The refractory metal liner may include any conventional liner material such as ruthenium and/or any other refractory metals such as tantalum (Ta), titanium (Ti), tungsten (W), iridium (Jr), rhodium (Rh) and platinum (Pt), etc., and/or mixtures thereof.

Sets of contact structures 174, 176 may be formed in openings 260, 254 of source/drain regions 230, 128, respectively, and on liner 230. Although not shown, contact structures 174, 176 may traverse fins 108a, 108b. FIGS. 13a and 13b show cross-sectional view of the contact structures. Contact structures 174, 176 may be formed by conventional semiconductor fabrication techniques for forming a contact structure, as described above with respect to FIGS. 8a and 8b. For example, set of contact structures 174, 176 may be formed by deposition, metallization and planarization. Set of contact structures 174, 176 may include, for example, tungsten (W), cobalt (Co), ruthenium (Ru), and/or any other now known or later developed materials for a contact structure. For example, set of contact structures 174, 176 may be formed by plasma vapor deposition (PVD) and/or atomic later deposition (ALD) of titanium (Ti); thermal annealing of the titanium (Ti); ALD of titanium nitride (TiN) layer; ALD of tungsten (W); and chemical mechanical planarization (CMP) of the tungsten.

Forming set of contact structures 174, 176 within non-uniformly gouged source/drain regions 230, 128, respectively, in NFET 224 and PFET 226 may, for example, accommodate the different desirable amounts of source/drain region gouging for an NFET and PFET structure formed therefrom. With respect to NFET 224, set of contact structures 174, 176 may be formed deeper within source/drain regions 230 of fin 108a of NFET 224 than within source/drain regions 128 of 108b of PFET 226. Forming set of contact structures 174, 176 deeper within source/drain regions 230 may, for example, reduce stress within the source/drain regions, as may be desirable for the NFET. With respect to PFET 226, forming set of contact structures 174, 176 shallower within openings 254 of source/drain regions 128 may, for example, maintain stress within the source/drain regions, as may be desirable for the PFET. For example, the stress within source/drain regions 128 before forming openings 254 may be approximately 0.5 gigapascals (GPa) to approximately 205 gigapascals (GPa), and the stress within source/drain regions 128 after forming openings 254 may be approximately 0.45 gigapascals (GPa) to approximately 2.45 gigapascals (GPa). Additionally, as discussed above with respect to FIG. 3b, forming contact structures 174, 176 to upper region 140 of source/drain regions 128 which may include a high percentage of germanium, may, for example, further decrease the electrical resistance as may be desirable for a PFET structure. With respect to both NFET 224 and PFET 226, forming sets of contact structures 174, 176 within openings 260, 254 of source/drain regions 230, 128, respectively, may, for example, increase contact area between the contact structures and the source/drain regions, which may reduce electrical resistance at the interface.

Replacement contact structures 174, 176 formed to non-uniformly gouged source/drain regions 230, 128 may therefore accommodate the differing desirable amounts of source/drain region gouging for a PFET and NFET structure.

The method as described above is used in the fabrication of integrated circuit chips. The method and structure is not limited to planar transistor technology and may be used, for example, in Fin Field Effect Transistor (FinFET) technology, etc. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

1. A complimentary N-type field effect transistor (NFET) structure and P-type field effect transistor (PFET) structure of an integrated circuit (IC) structure comprising:
a first fin of the NFET structure positioned on a substrate;
a second fin of the PFET structure positioned on the substrate, the first fin laterally separated from the second fin;
a gate structure positioned on the first fin and the second fin;
a first source/drain region of the first fin positioned adjacent to the gate structure, the first source/drain region including a first opening in an upper portion of the first source/drain region;
a second source/drain region of the second fin positioned adjacent to the gate structure, wherein an uppermost surface of the second source/drain region is positioned higher than a bottommost surface of the first opening in the first source/drain region, and wherein an uppermost portion of the second source/drain region includes a higher concentration of germanium than a bottommost portion of the second source/drain region;
a first set of contact structures positioned on the first source/drain region adjacent to the gate structure, wherein a portion of the first set of contact structures is positioned within the first opening of the first source/drain region; and
a second set of contact structures positioned directly on the uppermost portion of the second source/drain region adjacent to the gate structure, wherein a bottommost portion of the second set of contact structures is positioned higher than a bottommost portion of the first set of contact structures.

2. The IC structure of claim 1, wherein the second source/drain region includes a second opening, wherein a bottommost portion of the second opening is positioned higher than the bottommost surface of the first opening, and wherein a portion of the second set of contact structures is positioned within the second opening of the second source/drain region.

3. The IC structure of claim 2, wherein the bottommost surface of the first opening is positioned lower than an uppermost surface of the first fin; and wherein the bottommost portion of the second opening is positioned higher than an uppermost surface of the second fin.

4. The IC structure of claim 1, wherein the bottommost surface of the first opening is positioned lower than an uppermost surface of the first fin; and wherein the uppermost surface of the second source/drain region is positioned higher than an uppermost surface of the second fin.

5. The IC structure of claim 1, wherein the first source/drain region includes a raised source/drain region.

6. The IC structure of claim 1, wherein the second source/drain region includes a raised source/drain region.

7. (canceled)

8. The IC structure of claim 1, wherein each contact structure of the first set of contact structures and the second set of contact structures includes a first liner positioned along sides of each contact structure adjacent to the gate structure, and wherein the first liner of each contact structure of the second set of contacts structures contacts the uppermost surface of the second source/drain region.

9. The IC structure of claim 1, further comprising a second liner contacting a sidewall of the second source/drain region.

10. The IC structure of claim 1, wherein the first source/drain region includes silicon phosphorus.

11. The IC structure of claim 1, wherein the second source/drain region includes silicon germanium.

12. (canceled)

13. (Withdrawn- Previously Presented) A method of forming an integrated circuit (IC) structure, the method comprising:
forming a sacrificial gate structure on a N-type fin and a P-type, each fin positioned on a substrate, the N-type fin laterally separated from the P-type fin;
forming a first source/drain region on the P-type fin, the first source/drain region adjacent to each side of the sacrificial gate structure;
forming a liner above the first source/drain region;
forming a pair of openings in the N-type fin, the set of openings adjacent to each side of the sacrificial gate structure; and
forming a second source/drain region in the set of openings in the N-type fin, wherein a vertical cross-section of an uppermost surface of the second source/drain region is substantially U-shaped.

14. (Withdrawn- Previously Presented) The method of claim 13, further comprising after the forming the second source/drain region:
forming a first set of dummy contact structures on the first source/drain region and second set of dummy contact structures on the second source/drain region;
removing the sacrificial gate structure from the N-type fin and the P-type fin; and
forming a replacement metal gate structure on the N-type fin and the P-type fin.

15. The method of claim 14, further comprising after forming the replacement metal gate structure, forming a first set of contact structures to the first source/drain region and a second set of contact structure to the second source/drain region.

16. The method of claim 15, further comprising, before the forming the set of contact structures, removing a first portion of the second source drain region and a second portion of the first source drain region.

17. The method of claim 16, wherein a vertical cross-section of an uppermost surface of the first source/drain region is U-shaped, and wherein a bottommost point of the uppermost surface of the first source/drain region is positioned lower than a bottommost point of the uppermost surface of the second source/drain region.

18. The method of claim 16, wherein a first stress of the first source/drain region after the removing the second portion of the first source/drain region is approximately equal to a second stress of the first source/drain region before the removing the second portion of the first source/drain region.

19. A method of forming an integrated circuit (IC) structure, the method comprising:
forming a first source/drain region on a first fin of a P-type field effect transistor (PFET) positioned on a substrate, the first source/drain region positioned laterally adjacent to a gate structure positioned on the first fin;
forming a second source/drain region on a second fin of an N-type field effect transistor (NFET) positioned on the substrate, the second source/drain region positioned laterally adjacent to the gate structure positioned on the second fin, and wherein the first fin is laterally separated from the first fin;
forming a liner along sidewalls of the gate structure;
removing a first portion of the first source/drain region and a second portion of the second source/drain region;
forming a protective mask above the first source/drain region of the PFET; and
removing a third portion of the second source/drain region.

20. The method of claim 19, further comprising:
removing the protective mask from above the first source/drain region of the PFET;
forming a first set of contact structures on the first source/drain region; and
forming a second set of contact structure to the second source/drain region.
